(19) United States
(12) Patent Application Publication
(10) Pub. No.: US 2013/0020465 A1
(43) Pub. Date: Jan. 24, 2013

(54) PIXEL, PIXEL ARRAY, IMAGE SENSOR INCLUDING THE SAME, AND METHOD FOR DRIVING IMAGE SENSOR

(71) Applicants: Seung Hoon Sa, Seoul (KR); Woon Il Choi, Seoul (KR)

(72) Inventors: Seung Hoon Sa, Seoul (KR); Woon Il Choi, Seoul (KR)

(73) Assignee: LG Innotek Co., Ltd., Seoul (KR)

(21) Appl. No.: 13/246,266

(22) Filed: Sep. 27, 2011

(30) Foreign Application Priority Data
Jul. 20, 2011 (KR) 10-2011-0071734

(51) Int. Cl. H01L 27/148; H01L 27/144

(52) U.S. Cl. 250/208.1; 257/431; 257/443; 257/E27.127; 257/E27.15

(57) ABSTRACT

Disclosed are a pixel, a pixel array, an image sensor including the same, and a method for driving the image sensor. The method for driving the image sensor includes starting an integration procedure of charges in a photoelectric conversion part, transferring the charges, which are integrated in the photoelectric conversion part for a first integration duration, into a charge storage part, reading a signal level of the first integration duration, transferring charges, which are integrated in the photoelectric conversion part for a second integration duration after the first integration duration, into the charge storage part, reading a signal level of the second integration duration, and calculating a light intensity by using the signal level of the first integration duration and the signal level of the second integration duration. A WDR image sensor is provided to detect all light intensities regardless of the degree of illuminance.

### CROSS-REFERENCE TO RELATED APPLICATION

This application claims the benefit under 35 U.S.C. §119 of Korean Patent Application. No. 10-2011-0071734, filed on Jul. 20, 2011, which is hereby incorporated by reference in its entirety.

### BACKGROUND

The embodiment relates to a pixel, a pixel array, an image sensor including the same, and a method for driving the image sensor, capable of detecting all light intensities regardless of the degree of illuminance by using an existing 4T pixel structure.

A dynamic range is one of important factors to determine the quality of an image sensor. In general, the dynamic range refers to the maximum range for processing signals without distorting input signals. In the case of the image sensor, images having the superior quality can be obtained as the dynamic range becomes widened regardless of the brightness variation.

However, according to the color image sensor of the related art, the dynamic range is so narrow that the original color of the image may not be expressed well when one of red, green and blue colors is saturated. In order to solve the problem caused by the narrow dynamic range, a WDR (wide dynamic range) pixel has been suggested.

For instance, there has been suggested a method of realizing the WDR operation by adjusting irradiation time of the light in the image sensor of the related art.

In addition, there has been suggested a method of providing an additional capacitor to change FD (floating diffusion) capacity, in which a pixel structure includes a transistor to adjust the additional capacitor so that overflow charges, which are generated from a PD (photodiode) under the high intensity of illumination as light intensity is increased, can be stored in the additional capacitor.

Further, there has been suggested a method of providing a WDR pixel, in which two PDs are installed in one pixel such that charges generated from the two PDs are combined with each other.

However, according to the above methods, the sensitivity is constant regardless of the variation of light intensity (that is, high intensity of illumination and low intensity of illumination), so that the image may be darkened under the low intensity of illumination. In addition, while the pixel is being operated, the timing adjustment for the pixel operation under the high intensity of illumination may be limited.

Further, in the ease of the method for improving the sensitivity according to the light intensity by using the additional capacitor and the transistor and the method for driving two PDs installed in one pixel, the fill factor in the pixel may be reduced.

### BRIEF SUMMARY

The embodiment provides a WDR pixel capable of detecting lights regardless of the degree of illuminance without an additional photoelectric device or additional power, a pixel array, and an image sensor.

According to the embodiment, there is provided a pixel including a photoelectric conversion part to integrate charges for first and second integration durations different from each other by converting detected light into the charges, a charge storage part to store the charges obtained from the photoelectric conversion part, a transfer switching part to transfer the charges from the photoelectric conversion part to the charge storage part as an operating voltage is applied thereto, a reset switching part to drain the charges of the photoelectric conversion part and the charge storage part as the operating voltage is applied thereto, and an output part to output the charges stored in the charge storage part. The transfer switching part transfers the charges of the photoelectric conversion part into the charge storage part after the first integration duration.

According to the embodiment, there is provided a method for driving an image sensor including starting an integration procedure of charges in a photoelectric conversion part, transferring the charges, which are integrated in the photoelectric conversion part for a first integration duration, into a charge storage part, reading a signal level of the first integration duration, transferring charges, which are integrated in the photoelectric conversion part for a second integration duration after the first integration duration, into the charge storage part, reading a signal level of the second integration duration, and calculating a light intensity by using the signal level of the first integration duration and the signal level of the second integration duration.

As described above, the embodiment can provide a pixel capable of detecting a light regardless of the degree of illuminance by reducing charge integrationtime for high illuminance.

### BRIEF DESCRIPTION OF THE DRAWINGS

FIG. 1 is a circuit diagram showing a pixel array according to one embodiment;

FIG. 2 is a timing diagram showing the pixel array of FIG. 1;

FIG. 3 is a graph showing a signal intensity as a function of a light intensity in a pixel array according to one embodiment;

FIG. 4 is a circuit diagram showing a pixel array according to another embodiment;

FIG. 5 is a timing diagram showing the pixel array of FIG. 5;

FIG. 6 is a circuit diagram showing a pixel array according to still another embodiment; and

FIG. 7 is a flowchart showing a method of driving an image sensor according to one embodiment.

### DETAILED DESCRIPTION

In the description of the embodiments, it will be understood that, when a layer (or film), a region, a pattern, or a structure is referred to as being “on” or “under” another substrate, another layer (or film), another region, another pad, or another pattern, it can be “directly” or “indirectly” on the other substrate, layer (or film), region, pad, or pattern, or one or more intervening layers may also be present. Such a position of the layer has been described with reference to the drawings.

The thickness and size of each layer shown in the drawings may be exaggerated, omitted or schematically drawn for the purpose of convenience or clarity. In addition, the size of elements does not utterly reflect an actual size.

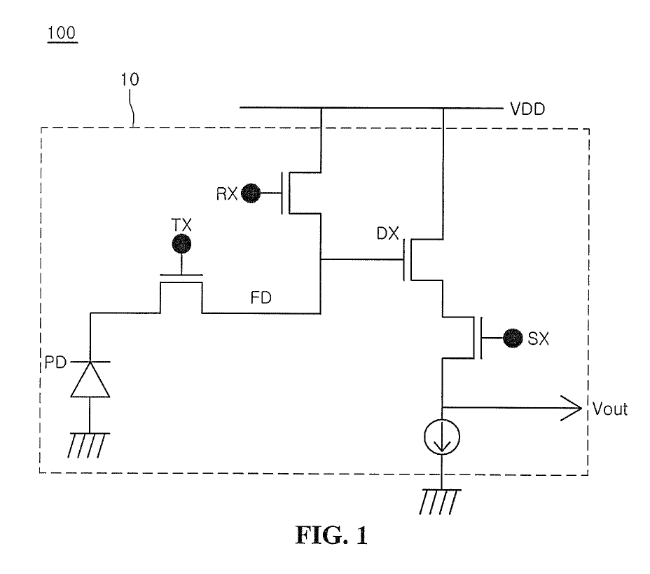

FIG. 1 is a circuit diagram showing a pixel array according to one embodiment. Although FIG. 1 shows a pixel array 100 including a unit pixel circuit 10 and a power supply VDD, the pixel array 100 according to one embodiment may include a plurality of pixels having the form of a pixel. FIG. 1 shows only the unit pixel 10.

Referring to FIG. 1, the pixel array 100 according to the embodiment includes a photoelectric conversion part PD, a charge storage part FD thnried on a substrate and provided at one side of the photoelectric conversion part PD to store charges obtained from the photoelectric conversion part PD, a transfer switching part TX provided at one side of the photoelectric conversion part PD on the substrate to transfer the charges of the photoelectric conversion part PD to the charge storage part FD, and a reset switching part RX to drain the charges of the charge storage part FD to the power supply VDD. In addition, the pixel 10 may include an output part to output information about the quantity of charges stored in the charge storage part FD. The output part may include at least one of a drive switching part DX, a selective switching part SX, and an output voltage terminal Vout shown in FIG. 1.

The switching parts TX, RX, DX, and SX shown in FIG. 1 may include a CMOS transistor, and the charge storage part (FD, floating diffusion region) may include a capacitor. In addition, the pixel array 100 further includes the power supply VDD. If a plurality of pixel circuit are provided, the pixel circuits may share the power supply VDD.

The photoelectric conversion part PD integrates lights, converts the lights into charges, and integrates the charges. The photoelectric conversion part PD may include a photodiode. The charges integrated in the photoelectric conversion part PD may be transferred to the charge storage part FD as an operating voltage is applied to the transfer switching part TX.

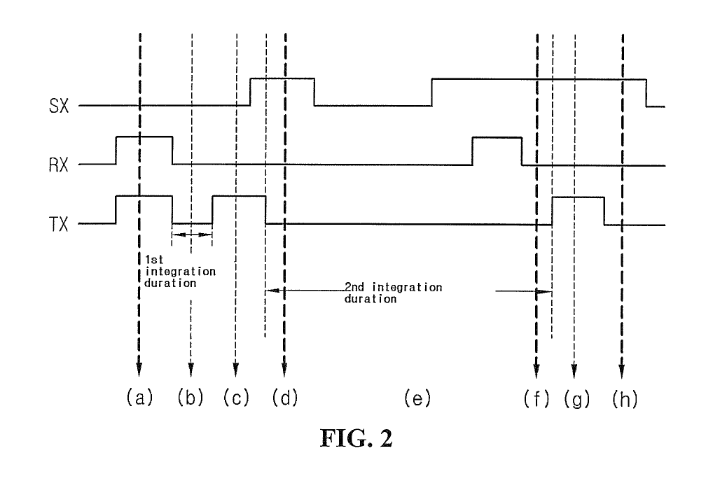

Meanwhile, the photoelectric conversion part PD according to one embodiment individually may integrate charges for different integration durations, for example, first and second integration durations. The first integration duration may be used to detect high-illuminance light and may be set to a length shorter than the length of the second integration duration. The first integration duration is a duration in which the overflow of charges, that is, the blooming of charges does not occur in the photoelectric conversion part PD even if a light representing the maximum illuminance is incident. The size of the first integration duration may be determined according to the charge storage capacity (i.e., capacitance) of the photoelectric conversion part PD. Details thereof will be described later with reference to FIG. 2.

The second integration duration may be a duration in which charges are integrated after the first integration duration, and a light representing an intermediate or low illuminance is detected. Differently from the first integration duration, the overflow of charges in the photoelectric conversion part PD is not important for the second integration duration. In a high illuminance, the overflow of charges may occur in the photoelectric conversion part PD for the second integration duration. In this case, light intensity may be determined based on the quantity of charges detected for the first integration duration. Meanwhile, in the intermediate or low illuminance, the overflow of charges does not occur in the photoelectric conversion part PD for the second integration duration. In this case, the light intensity may be determined based on the quantity of charges detected for the second integration duration because charges are hardly produced or charges are less in quantity for the first integration duration in the case of the intermediate illuminance or low illuminance.

The transfer switching part TX can transfer charges of the photoelectric conversion part PD into the charge storage part FD according to the operating voltage applied to the transfer switching part TX. In this case, the transfer switching part TX may be driven at the end time point of the first integration duration and the end time point of the second integration duration. Based on the time points to drive the transfer switching part TX, the sizes of the first and second integration durations can be determined.

The charge storage part FD may include a capacitor having one end connected to the transfer switching part TX and an opposite end connected to a grounding terminal. In addition, the charge storage part FD can be reset by the reset switching part RX.

When a reset control signal is applied to a gate of the reset switching part RX, the reset switching part RX removes photocharges stored in the charge storage part FD in response to the reset control signal.

The drive switching part DX can transfer the charges stored in the charge storage part FD to the output voltage terminal Vout. The drive switching part DX may act as an amplifier such as a source follower.

Meanwhile, although not shown in FIG. 1, the pixel array 100 according to the embodiment further includes an operation part to calculate optical intensity by using the information about the quantity of charges read in the output voltage terminal Vout.

FIG. 2 is a timing diagram showing the pixel array of FIG. 1.

In step (a), the reset switching part RX and the transfer switching part TX are turned on to remove charges of the photoelectric conversion part PD and the charge storage part FD by draining the charges of the photoelectric conversion part PD and the charge storage part FD. Thereafter, the reset switching part RX and the transfer switching part TX are turned off, so that a charge integration procedure can be started.

In step (b), charges are started to be integrated in the photoelectric conversion part PD for the first integration duration. As described above, the first integration procedure is to detect a high-illuminance light. The first integration procedure may be set with a shorter duration so that the photoelectric conversion part PD is not overflowed even if the high-illuminance light is incident for a corresponding duration. Accordingly, the first integration duration may depend on the expected light intensity representing the maximum illuminance, for example, a preset light intensity of a high illuminance. In addition, the first integration duration may depend on the charge storage capacity of the photoelectric conversion part PD.

In step (c), the transfer switching part TX is turned on, so that the charges stored in the photoelectric conversion part PD for the first integration duration are transferred to the charge storage part FD.

In step (d), the information about the quantity of charges stored for the first integration duration is output and read out.

In step (e), the integration of charges is started in the photoelectric conversion part PD for the second integration duration. The second integration duration is a duration in which a light representing an intermediate illuminance or a low illuminance is detected as described above. For the second integration duration, the photoelectric conversion part PD may be overflowed or not.

In step (f), the reset switching part RX is turned on and turned off to output and read a reset signal.

In step (g), the transfer switching part TX is turned on again to transfer charges, which are stored in the photoelectric conversion part PD for the second integration duration, to the charge storage part FD.

In step (h), the information about the quantity of charges for the second integration duration is output and read.

Meanwhile, in steps (d) and (h), the light intensity can be calculated by using the read information about the quantity of charges. For example, when the size of the first integration duration is 1/10 as great as the size of the second integration duration, and when the signal detected for the first integration duration is about 0.1V, and the output information about the quantity of charges detected for the second integration duration is about 5V, the light intensity may be μ(0.1*10+5), in which the μ may serve as a pixel constant representing voltage as a function of the light intensity (V/lux).

In other words, when the size of the first integration duration to the size of the second integration duration is m, the information about the quantity of charges read for the first integration duration is k1, and the information about the quantity of charges read for the second integration duration is k2, the real information about the quantities of charges detected in the pixel may be (k1*m+k2), and the light intensity may be determined in proportional to the (k1*m+k2).

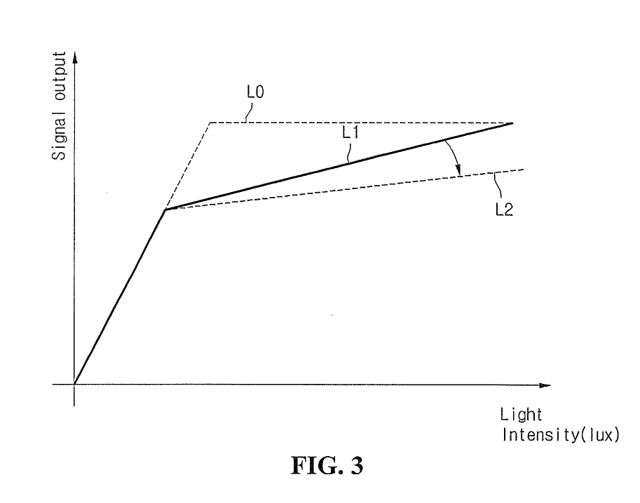

FIG. 3 is a graph showing a signal intensity as a function of a light intensity in the pixel array according to one embodiment. Referring to FIG. 3, L0 represents a curve of an output signal as a function of the light intensity read out of a 4T image sensor according to the related art, and L1 represents a curve when the first integration duration for detecting the high-illuminance light is additionally set. The duration, in which the light intensity is L or less, represents an intermediate illuminance duration, and the duration, in which the light intensity is L or more, represents a high illuminance duration. The L determining the boundary between the intermediate and high illuminances may depend on the lengths of the first and second integration durations.

Meanwhile, when the charge storage capacity of the photoelectric conversion part PD is increased, the gradient of the graph may be reduced from L1 to L2. In addition, the dynamic range is more widened.

In addition, even when the length of the first integration duration is shortened, the gradient of the graph may be reduced. In this case, the light intensity point L determining the boundary between the intermediate and high illuminances may be moved into the right of the graph. However, since the expansion degree of the detection range of an intermediate or low-illuminance light is less than the expansion degree of the detection range of a high-illuminance light, the movement degree of the light intensity point L may be relatively low.

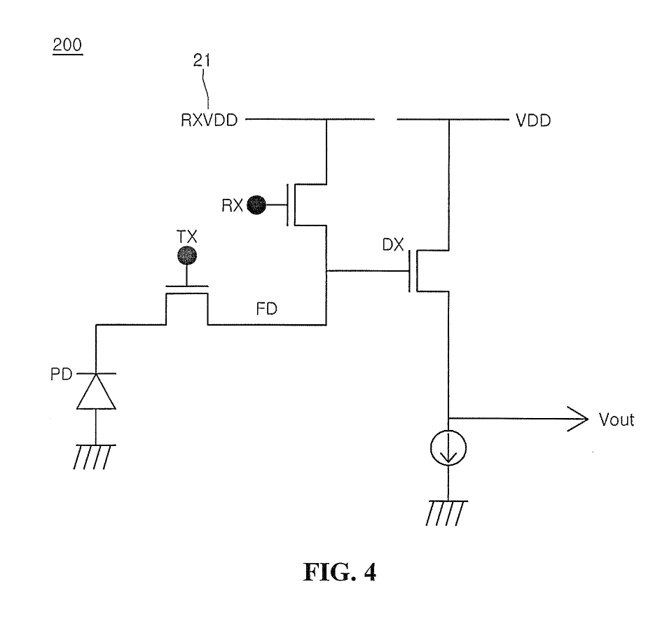

FIG. 4 is a circuit diagram showing a pixel array 200 according to another embodiment. Referring to FIG. 4, the pixel array 200 further includes a reset power supply RXVDD electrically connected to the reset switching part RX, thereby individually adjusting the power supply voltage of the reset switching part RX. When the voltage of the reset power supply RXVDD is applied to the reset switching part RX, only charges may be drained. Therefore, a specific pixel is selected without the selective switching part SX, so that a signal can be read out. In addition, the selective switching part SX is not employed, so that a high fill factor can be maintained, and the pixel array 200 can be driven regardless of the voltage adjustment of the transistors to drive pixels according to the related art.

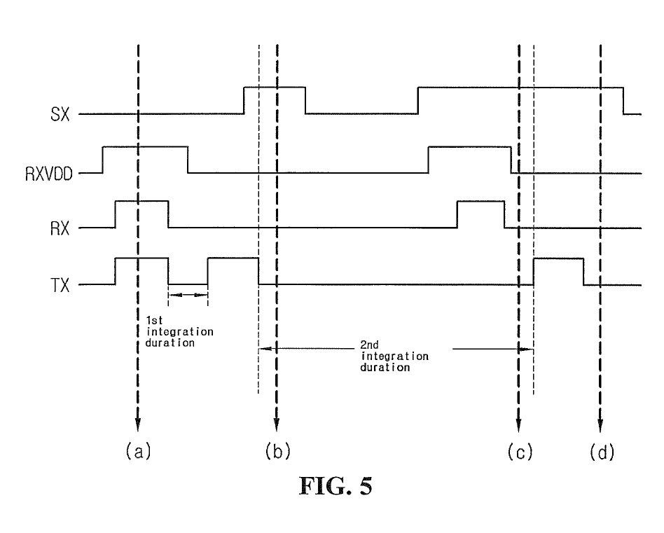

FIG. 5 is a timing diagram showing the pixel array of FIG. 4. Differently from the timing diagram shown in FIG. 3, the timing diagram of FIG. 5 has no driving timing of the selective switch part SX. The reset power supply RXVDD can receive power in the driving timing of the reset switching part RX for the purpose of driving the reset switching part RX.

In step (a), the voltage of the reset power supply RXVDD is applied, so that the reset switching part RX is driven. Simultaneously, the transfer switching part TX is driven, so that charges are removed from the photoelectric conversion part PD and the charge storage part FD.

In step (b), the transfer switching part TX is turned on or turned off to output and read out the quantity of charges stored by the high-illuminance light for the first integration duration.

In step (c), power is applied to the reset power supply RXVDD, so that the reset signal is read out.

In step (d), the transfer switching part TX is turned on and turned off to output and read the quantity of charges stored by the intermediate or low illuminances for the second integration duration.

In addition, since the charge integration procedures for the first and second integration duration, duration setting, and light intensity calculation are the same as those of FIG. 3, the details thereof will be omitted.

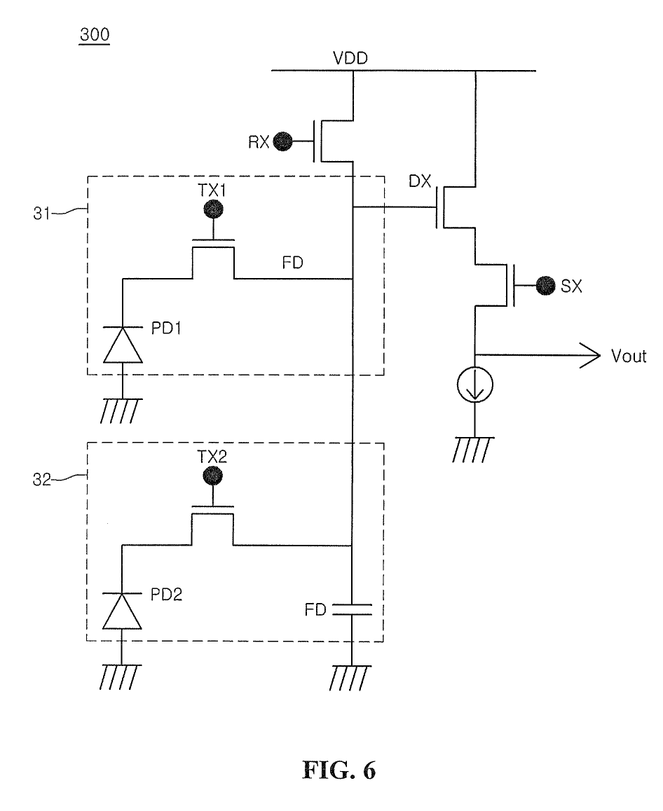

FIG. 6 is a circuit diagram showing a pixel array 300 according to still another embodiment. Referring to FIG. 6, the pixel array 300 further includes a circuit 32 including a photoelectric conversion part PD2 and a transfer switching part TX2, in addition to a circuit 31 including a photoelectric conversion part PD1 and a transfer switching part TX1. The circuits 31 and 32 share at least one of the charge storage part FD, the reset switching part RX, and an output part.

The circuit 31 can constitute a unit pixel independent from that of the circuit 32.

In addition, the circuit 31 and 32 can detect an intermediate illuminance duration or a low illuminance duration and a high-illuminance duration, respectively. For example, the photoelectric conversion part PD1 of the circuit 31 can detect a light only for the first integration duration, and the photoelectric conversion part PD2 of the circuit 32 can detect a light only for the second integration duration. The selective switching part SX can output and read signals according to timings of the integration durations.

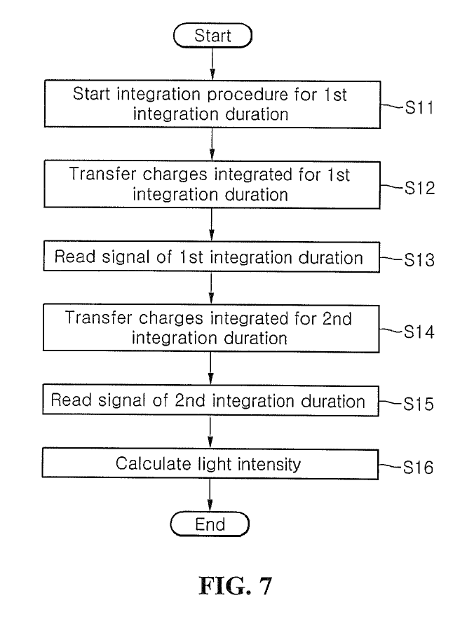

FIG. 7 is a flowchart showing a method for driving an image sensor according to one embodiment.

In step S11, the charge integration of the photoelectric conversion part is started for the first integration duration. Meanwhile, before the charge integration procedure for the first integration duration, the reset switching part and the transfer switching part are turned on to drain charges of the photoelectric conversion part and the charge storage part, so that the charges of the photoelectric conversion part and the charge storage part can be removed. The charge integration procedure of the first integration duration can be started at a time point when both of the reset switching part and the transfer switching part are turned off.

In step S12, the transfer switching part is driven to transfer charges integrated for the first integration duration into the charge storage part. The first integration duration may be ended at a time point when the transfer switching part is turned on.

In step S13, the signal level produced by charges integrated for the first integration duration is read.

In step S14, charges integrated for the second integration duration are transferred. Before the step S14, charges are integrated in the photoelectric conversion part for the second integration duration. The second integration duration may be a duration from a time point of terminating the charge transferring procedure by turning off the transfer switching part to a time point of turning on the transfer switching part again.

In step S15, a signal level of charges, which are integrated for the second integration duration and transferred into the charge storage part, is read.

In step S16, the whole light intensity can be calculated by using signal levels read in steps S13 and S15. In detail, the intensity of the high-illuminance light integrated for the first integration duration and the intensity of the intermediate and low illuminance lights integrated for the second integration duration are subject to an operation, so that the whole light intensity can be obtained.

As described above, according to one embodiment, there is provided a WDR pixel, a pixel array, an image sensor including the same, and a method for driving the image sensor, capable of detecting lights representing all illuminances by adjusting timing in the structure of a 4T image sensor according to the related art.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component pails and/or arrangements, alternative uses will also be apparent to those skilled in the art.

What is claimed is:

1. A pixel comprising:
a photoelectric conversion part to integrate charges for first and second integration durations different from each other by converting detected light into the charges;
a charge storage part to store the charges obtained from the photoelectric conversion part;
a transfer switching part to transfer the charges from the photoelectric conversion part to the charge storage part as an operating voltage is applied thereto;
a reset switching part to drain the charges of the photoelectric conversion part and the charge storage part as the operating voltage is applied thereto; and
an output part to output the charges stored in the charge storage part,
wherein the transfer switching part transfers the charges of the photoelectric conversion part into the charge storage part after the first integration duration.

2. The pixel of claim 1, wherein the first integration duration is a charge integration duration based on a high-illuminance light, and is shorter than the second integration duration.

3. The pixel of claim 1, wherein the first integration duration is set based on at least one of a preset high-illuminance light intensity and a charge storage capacity of the photoelectric conversion part.

4. The pixel of claim 1, wherein the transfer switching part transfers the charges of the photoelectric conversion part into the charge storage part after the second integration duration.

5. The pixel of claim 1, wherein the charges of the photoelectric conversion part and the charge storage part are removed before the first integration duration.

6. The pixel of claim 1, further comprising a reset power supply to independently operate the reset switching part, wherein the charges are drained when reset power supply voltage is applied to the reset switching part.

7. The pixel of claim 1, further comprising a second photoelectric conversion part to detect a light and to integrate charges and a second transfer switching part to transfer the charges from the second photoelectric conversion part to the charge storage part, wherein the second photoelectric conversion part and the second transfer switching part share the charge storage part and the reset switching part.

8. A pixel array comprising the pixel claimed in claim 1.

9. An image sensor comprising the pixel array claimed in claim 8.

10. A method for driving an image sensor including at least one pixel, the method comprising:
starting an integration procedure of charges in a photoelectric conversion part;
transferring the charges, which are integrated in the photoelectric conversion part for a first integration duration, into a charge storage part;
reading a signal level of the first integration duration;
transferring charges, which are integrated in the photoelectric conversion part for a second integration duration after the first integration duration, into the charge storage part;
reading a signal level of the second integration duration; and
calculating a light intensity by using the signal level of the first integration duration and the signal level of the second integration duration.

11. The method of claim 10, wherein the first integration duration is a charge integration duration based on a high-illuminance light, and is shorter than the second integration duration.

12. The method of claim 10, wherein the first integration duration is set based on at least one of a preset high-illuminance light intensity and a charge storage capacity of the photoelectric conversion part.

13. The method of claim 10, further comprising removing the charges from the photoelectric conversion part and the charge storage part before the first integration duration.

14. The method of claim 10, wherein the first integration duration is set based on at least one of photosensitivity and terminal capacitance of the photoelectric conversion part.

15. The method of claim 10, wherein the pixel includes a reset power supply to independently operate a reset switching part, and the method further comprises draining the charges of the photoelectric conversion part and the charge storage part.

16. The method of claim 10, wherein the pixel includes a second photoelectric conversion part to detect a light and to integrate charges and a second transfer switching part to transfer the charges, which are integrated in the photoelectric conversion part, to the charge storage part, and the second photoelectric conversion part and the second transfer switching part share the charge storage part and a reset switching part.

17. The method of claim 16, wherein the second photoelectric conversion part detects a light for the first integration duration, and the photoelectric conversion part detects a light only for a second integration duration.

18. A pixel array comprising the pixel claimed in claim 2.

19. A pixel array comprising the pixel claimed in claim 3.

20. A pixel array comprising the pixel claimed in claim 4.

21. A pixel array comprising the pixel claimed in claim 5.
